(19) United States
(12) Patent Application Publication
(10) Pub. No.: US 2014/0178720 A1
(43) Pub. Date: Jun. 26, 2014

(54) MEASURING METHOD FOR AN ELECTROCHEMICAL ENERGY STORAGE DEVICE AND MEASURING APPARATUS

(71) Applicants: Michael Rentzsch, Dresden (DE); Jens Meintschel, Bernsdorf (DE); Claus-Rupert Hohenthanner, Hanau (DE); Joerg Kaiser, Eggenstein (DE); Denny Thiemig, Moritzburg (DE)

(72) Inventors: Michael Rentzsch, Dresden (DE); Jens Meintschel, Bernsdorf (DE); Claus-Rupert Hohenthanner, Hanau (DE); Joerg Kaiser, Eggenstein (DE); Denny Thiemig, Moritzburg (DE)

(73) Assignee: Li-Tec Battery GmbH, Kamenz (DE)

(21) Appl. No.: 14/115,486

(22) PCT Filed: Apr. 26, 2012
(86) PCT No.: PCT/EP2012/001797

§ 371 Date: Mar. 10, 2014

(30) Foreign Application Priority Data
May 5, 2011 (DE) 10 2011 100 605.6

(51) Int. Cl. G01R 31/36; H01M 10/633

(52) U.S. Cl. CPC G01R 31/3606; H01M 10/5022
USPC 429/61; 324/426

(57) ABSTRACT

The measurement method according to the invention for an electrochemical energy storage device involves the electrochemical energy storage device being held (S1) and having contact made with it (S2) in a holding device. The electrochemical energy storage device is charged (S3) to a predetermined first charge state. The electrochemical energy storage device is discharged (S4) to a predetermined second charge state. A measuring device is used to capture (S5) at least one measured value for a physical parameter of the electrochemical energy storage device, with the physical parameter allowing the operating state of the electrochemical energy storage device to be inferred.

The entire content of the DE 10 2011 100 605 priority application is fully incorporated as an integral part of the present application by reference herein.

The present invention relates to a measuring method for an electrochemical energy storage device and a measuring apparatus, particularly for performing the measuring method. The invention will be described in connection with substantially prismatic electrochemical cells. However, it is pointed out that the invention can also be used independently of the geometry of the battery cells.

Charge cycles are also noted in connection with rechargeable electrochemical energy storage devices. A charge cycle thereby refers to the charging of an electrochemical energy storage device and its subsequent discharging, for example to supply a load, whereby depending on convention, the charging process can also follow a discharging process. Experience shows that with an increasing number of charge cycles, the ability of such energy storage devices to absorb and release electrical energy drops. The number of charge cycles after which the energy storage device is still able to absorb or release a predetermined portion of the original amount of charge or energy respectively or which the energy storage device undergoes without appreciable aging is a measure of the quality of such energy storage devices. “Long-term stability” is another term for this sustainable number of charge cycles.

Electrochemical energy storage devices seen as having insufficient long-term stability are known from the prior art.

The present invention is thus based on the object of providing a method by means of which knowledge can be gained on the operational behavior of electrochemical energy storage devices.

This is achieved in accordance with the invention by the teaching of the independent claims. Claim 1 relates to a measuring method for an electrochemical energy storage device. Claim 5 relates to a measuring apparatus for an electrochemical energy storage device, particularly for performing the measuring method. Preferential embodiments and further developments of the invention constitute the subject matter of the subclaims.

According to the inventive measuring method for an electrochemical energy storage device, the electrochemical energy storage device is received (S1) and contacted (S2) in a receiving device. The electrochemical energy storage device is charged at a predetermined charge current I_{L}(t) to a predetermined first state of charge (S3). The electrochemical energy storage device is discharged at a predetermined discharge current I_{E}(t) to a predetermined second state of charge (S4). At least one measured value on an physical parameter of the electrochemical energy storage device is acquired by the measuring apparatus (S5), whereby the physical parameter enables conclusions to be drawn as to the operating mode of the electrochemical energy storage device.

To be understood by an electrochemical energy storage device in the sense of the invention is a device, in particular serving the releasing and absorbing of electrical energy, in which electrical energy is converted into chemical energy or vice versa. To this end, the electrochemical energy storage device comprises an electrode assembly. The electrode assembly comprises at least one anode and one cathode. The electrode assembly further comprises a separator, wherein the separator is substantially impermeable to electrons. The electrochemical energy storage device further comprises at least one or two pole contacts. The electrochemical energy storage device further comprises a casing which delimits in particular the electrode assembly from the environment. The electrode assembly is preferably formed as a substantially prismatic electrode stack, as a substantially cylindrical electrode coil, as a so-called flat winding or as an electrode stack with a Z-shaped folded separator strip. Preferably, the electrochemical energy storage device is of substantially rectangular shape and comprises two substantially oppositely parallel boundary surfaces.

In the terms of the invention, a receiving device is to be understood as a device which encloses in particular the electrochemical energy storage device during the measuring method in form-locking, particularly force-fit, manner. Preferably, the receiving device comprises one or two abutment devices adapted to the geometry of the electrochemical energy storage device. Particularly one abutment device advantageously serves the boundary surface contact of the electrochemical energy storage device. It is particularly preferential for at least one abutment device to be of plate-shaped design. Particularly a plate-shaped abutment device advantageously serves the boundary surface contact of a substantially rectangular electrochemical energy storage device and/or the contact of a temperature control device.

According to one preferred embodiment, the receiving device comprises two substantially plate-shaped abutment devices arranged substantially parallel to one another. The in particular plate-shaped abutment devices are disposed so as to be movable relative to each other. The receiving device further comprises a guidance device. The guidance device serves in guiding one of the abutment devices. Preferably, the guidance device extends substantially vertically from the first abutment device toward the second abutment device. The second abutment device is supported by the guidance device so as to be relatively movable. It is particularly preferable for the guidance device to comprise two, three or four guide columns which extend through openings in the second abutment device.

Receiving in the sense of the invention refers in particular to the receiving device holding the electrochemical energy storage device during the measuring method, particularly between abutment devices. Advantageously, a minimum contact force acts on a surface area during the measuring method, particularly a boundary surface of the electrochemical energy storage device, in particular from one of the abutment devices, particularly due to the dead weight of one of the abutment devices or a force actuator. Doing so thus counteracts unwanted displacement of the electrochemical energy storage device during the measuring method.

Contacting in the sense of the invention refers in particular to the pole contacts of the electrochemical energy storage device each being connected to a power supply device. Preferably, a power supply device is configured as a power cable, a busbar, a current lead or the like. It is advantageous to be able to supply or withdraw electrical energy to/from the electrochemical energy storage device subsequent the contacting.

In the terms of the invention, an electrochemical energy storage device state of charge L in particular refers to the following relationship:

$$L = \frac{{Q}_{t}}{{Q}_{N}}$$

where Q_{N} is the nominal charge [Ah] or maximum charge respectively of the electrochemical energy storage device and Qₜ is the charge currently able to be tapped from the electrochemical energy storage device. It is also common in conjunction with electrochemical energy storage devices to refer to charging capacity instead of charge. Alternatively, the state of charge is in particular defined by the ratio of the energy [J] currently able to be tapped from the electrochemical energy storage device and the theoretical maximum energy which can be tapped. Predetermined states of charge L in the sense of the invention are in particular integral multiples of for instance 0.05; preferentially 0; 0.05; 0.1; 0.15; 0.2. 0.25; 0.3; 0.35; 0.4; 0.45; 0.5; 0.55; 0.6; 0.65; 0.7; 0.75; 0.8; 0.85; 0.9; 0.95 and 1. According to the invention, the first state of charge is higher, and the maximum charge closer, than the second state of charge. Preferably, the first state of charge is close to the nominal charge or the maximum charge respectively, whereby overloading the electrochemical energy storage device is to be avoided. Preferably, the second state of charge is to be selected close to the substantially full discharge of the electrochemical energy storage device or the state of charge in which further discharging would lead to damaging the electrochemical energy storage device, the so-called deep discharge, which is to be avoided.

The state of charge L further refers to the ratio of terminal voltage and theoretical voltage. In practice, the full charging of an electrochemical energy storage device is also defined by the presence of a maximum allowable terminal voltage. Likewise, a discharged state of the electrochemical energy storage device is also defined by the presence of a minimum allowable terminal voltage. Preferably, the minimum allowable terminal voltage amounts to 2.5; 2.7; 3.0; 3.1; 3.2; 3.3; 3.4; 3.5; 3.6; 3.7; 3.8; 3.9; 4.0; 4.1; 4.2; 4.3; 4.4; 4.5; 4.6; 4.7; 4.8; 4.9; 5.0; 5.1; 5.2 or 5.3 V.

To be understood by a physical parameter in the sense of the invention is in particular a parameter which allows inferring the state of an electrochemical energy storage device. Counting as physical parameters in the present case are in particular voltage, terminal voltage, current, resistance, temperature, pressure, and dimensions in particular of the electrochemical energy storage device such as length, height, thickness and diameter.

Also the force exerted by an electrochemical energy storage device on a contacting independent body is to be understood as a physical parameter in the sense of the invention. Evaluated parameters such as in particular the state of charge of an electrochemical energy storage device also count as a physical parameter in the sense of the invention. A combination of physical parameters characterizes an operating mode of the electrochemical energy storage device.

A measuring device in the sense of the invention is in particular to be understood as a device serving in detecting a physical parameter. Preferably, the measuring device comprises at least one of the following sensors, in particular: ammeter, voltage meter, temperature sensor, dynamometer, pressure measuring device and distance meter device. It is particularly preferential for the measuring device to comprise different sensors for different physical parameters. Preferably, the measuring device provides a voltage or a current which is representative of a measured value, particularly preferentially proportional to the measured value. The voltage or the current is advantageously suited for further processing by a display device, output device and/or control device.

Preferably a charge current and/or a discharge current is detected. The behavior of the electrochemical energy storage device at different charges is advantageously detected by means of the measuring method, wherein the behavior is particularly of interest to electrical currents, current-time plottings and/or current-time integrals. Preferably at least one voltage is detected, particularly the terminal voltage of the electrochemical energy storage device. The behavior of the electrochemical energy storage device at different voltages is advantageously detected by means of the measuring method. When the measured values of the current measurements and the voltage measurements are linked, particularly to the internal resistance, the behavior of the electrochemical energy storage device at different charges can then advantageously be determined. Preferably, at least one temperature of the electrochemical energy storage device is detected, particularly the temperature of an electrochemical energy storage device pole contact. It is particularly preferential to acquire temperatures at different locations on the electrochemical energy storage device. Advantageously, the behavior of the electrochemical energy storage device at different currents according to current-time plottings and/or current-time integrals is detected by means of the measuring method. Preferably at least one dimensional change to the electrochemical energy storage device accommodated in the receiving device is detected. Advantageously, a dimensional change to the electrochemical energy storage device at different states of charge, at different temperatures, subject to a predetermined force, particularly pressing force, and/or according to current-time plottings is detected by means of the measuring method.

In accordance with the invention, the “receiving” of the electrochemical energy storage device according to S1 does not necessarily precede the “contacting” according to S2. Depending on the design of the measuring device, S2 occurs before S1, in particular to facilitate the contacting.

In accordance with the invention, S2 occurs prior to S3 and S4. In further accordance with the invention, the “charging” of the electrochemical energy storage device according to S3 does not necessarily precede the “discharging” according to S4. Preferably, the electrochemical energy storage device is first charged when its state of charge is closer to the second state of charge than the first state of charge. When, however, the electrochemical energy storage device's state of charge is closer to the first state of charge, the electrochemical energy storage device is then preferably to be discharged first.

Measurements ensue according to S5 at least at the present first state of charge and present second state of charge. Preferably, the detecting of measured values according to S5 is repeated during the charging process of the electrochemical energy storage device according to S3. Preferably, the measured value acquisition according to S3 is repeated during the discharge process according to S4. It is particularly preferable for the measured value acquisition according to S5 to occur periodically during the charging or discharging of the electrochemical energy storage device at time intervals of predefined length, particularly after at least 1, 2, 5, 10, 20, 50, 100, 200, 500, 1000, 2000, 5000, 10,000, 20,000, 50,000 or more seconds have in each case elapsed.

The measuring method is inventively performed such that the electrochemical energy storage device assumes both the first state of charge as well as the second state of charge.

According to the invention, in the simplest case, a charge current or discharge current is temporally constant. Preferably, the charge current is temporally variable. Preferable is first charging with a constant current until a predetermined terminal voltage can be measured. Subsequently preferable is charging with a constant voltage until the charge current falls below a minimum value. Preferably, the charge current is pulsed, wherein the pulse voltage increases over time and assumes a target voltage near the end of the charging process. It is preferable for the discharge current to be temporally variable and particularly preferential to be adapted to discharge current profiles from the actual supply of a load. The discharge current thus exhibits intervals corresponding to a motor vehicle's intermittent accelerated motions. According to one preferential development, the discharge current corresponds to the charge of a normal driving cycle.

Charge currents and/or discharge currents particularly for determining the states of charge of an electrochemical energy storage device with given nominal charge Q_{N}[Ah], in practice also called nominal capacity C[Ah], are in particular selected as multiples or fractional multiples of the nominal charge Q_{N} or nominal capacity C respectively of the electrochemical energy storage device. Preferably, the charge current and the discharge current of a charging cycle or a plurality of successive charging cycles respectively are harmonized:
in particular same charge current (first value, before the slash) and discharge current (second value, after the slash) at particularly 0, 1C/0.1C; 0.25C/0.25C; 0.5C/0.5C; 1C/1C; 2C/2C; 3C/3C; 4C/4C; 5C/5C, 6C/6C, 7C/7C, 8C/8C, 9C/9C or 10C/10C;
in particular different charge current (first value, before the slash) and discharge current (second value, after the slash) at particularly 1C/2C; 1C/3C; 1C/4C; 1C/5C; 2C/1C; 2C/3C; 2C/4C; 2C/5C; 3C/1C; 3C/2C; 3C/4C; 3C/5C; 4C/1C; 4C/2C; 4C/3C; 4C/5C; 5C/1C; 5C/2C; 5C/3C; 5C/4C or another combination.

According to one preferred development, charge/discharge currents are pulsed-defined, particularly at an amperage corresponding to:
4 times the nominal capacity C or Q_{N} over a period of in particular 2 s, 8 s, 10 s, 18 s;
5 times the nominal capacity C or Q_{N} over a period of in particular 2 s, 8 s, 10 s, 18 s;
10 times the nominal capacity C or Q_{N} over a period of in particular 2 s, 8 s, 10 s, 18 s.

The inventive measuring method gives the expert information on the operational behavior of the electrochemical energy storage device received by the receiving device between the selected first and second states of charge. With this knowledge, the expert is able to limit the charge currents to a tolerable degree for the electrochemical energy storage device, both in terms of amperage as well as current duration, so as to in particular counter unwanted high temperatures. Thus, irreversible chemical reactions which accelerate the aging of the electrochemical energy storage device are advantageously countered. With knowledge of the temperatures, the expert can take appropriate temperature control measures, particularly improved cooling of the electrochemical energy storage device. The knowledge puts the expert in the position of being able to design the electrochemical energy storage device receiver such that a variable dimension at different states of charge does not lead to insufficient fixing of the electrochemical energy storage device in the receiver. Thus, damage due to in particular impacts or vibration are advantageously countered. The knowledge puts the expert in the position of being able to design the electrochemical energy storage device receiver such that a variable dimension at different states of charge does not lead to damaging forces on the electrochemical energy storage device, particularly due to the receiver being dimensioned too small and the electrochemical energy storage device being constricted. Advantageously, in designing the receiver, the expert can provide for space for temporary “growth” of the electrochemical energy storage device at higher states of charge. Damage to an electrode is thus prevented. Hence, the expert gains knowledge on the improved design of an electrochemical energy storage device, a gentler operation of the electrochemical energy storage device and its accommodation in a battery for longer-lasting operation, thus accomplishing the underlying object.

The following will describe preferential developments of the inventive measuring method.

According to one preferential development of the inventive measuring method, hereinafter referred to as M1, the electrochemical energy storage device is held in the receiving device, particularly between abutment devices, such that the electrochemical energy storage device is at least inhibited, preferably substantially prevented, from elongating along at least one axis particularly along the guidance device during operation. In the process, at least one force exerted by the electrochemical energy storage device on the receiving device, particularly as a function of different physical parameters, particularly as a function of different states of charge, is measured. Advantageously, the behavior of the electrochemical energy storage device in a substantially rigid battery receiver is reconstructed. Findings can be advantageously determined in the laboratory relative the in particular long-term consequences for the electrochemical energy storage device with such a receiver. Advantageously, knowledge can be gained on battery housing design so as to prevent disadvantageous constricting of the electrochemical energy storage device.

According to a further preferential development of the inventive measuring method, hereinafter referred to as M2, the electrochemical energy storage device is held in the receiving device, particularly between abutment devices, such that the electrochemical energy storage device can elongate along at least one axis during operation. In the process, an enlargement of at least one dimension of the electrochemical energy storage device along the cited axis is measured, particularly as a function of different physical parameters, particularly as a function of different states of charge.

According to a further preferential development of the inventive measuring method, in particular discharging ensues according to predetermined current-time plottings.

Charge currents and/or discharge currents particularly for determining the states of charge of an electrochemical energy storage device with given nominal charge Q_{N}[Ah], in practice also called nominal capacity C[Ah], are in particular selected as multiples or fractional multiples of the nominal charge Q_{N} or nominal capacity C respectively of the electrochemical energy storage device. Preferably, the charge current and the discharge current of a charging cycle or a plurality of successive charging cycles respectively are harmonized:
in particular road driving cycles from which result the amounts of charge [Ah] supplied and/or discharged to/from the electrochemical energy storage device;
in particular same charge current (first value, before the slash) and discharge current (second value, after the slash) at particularly 0, 1C/0.1C; 0.25C/0.25C; 0.5C/0.5C; 1C/1C; 2C/2C; 3C/3C; 4C/4C; 5C/5C, 6C/6C, 7C/7C, 8C/8C, 9C/9C or 10C/10C;
in particular different charge current (first value, before the slash) and discharge current (second value, after the slash) at particularly 1C/2C; 1C/3C; 1C/4C; 1C/5C; 2C/1C; 2C/3C; 2C/4C; 2C/5C; 3C/1C; 3C/2C; 3C/4C; 3C/5C; 4C/1C; 4C/2C; 4C/3C; 4C/5C; 5C/1C; 5C/2C; 5C/3C; 5C/4C or another combination.

According to one preferred development, charge/discharge currents are pulsed-defined, particularly at an amperage corresponding to:
4 times the nominal capacity C or Q_{N} over a period of in particular 2 s, 8 s, 10 s, 18 s;
5 times the nominal capacity C or Q_{N} over a period of in particular 2 s, 8 s, 10 s, 18 s;
10 times the nominal capacity C or Q_{N} over a period of in particular 2 s, 8 s, 10 s, 18 s.

These processes are impressed upon the electrochemical energy storage device during the measuring method. These processes are preferably gained from loads in practical operation. Advantageously, the behavior of electrochemical energy storage devices which occurs during operation can be reconstructed in the laboratory.

According to a further preferential development of the inventive measuring method, the measured values are acquired during the charging or discharging of the electrochemical energy storage device as a function of the supplied Q₊ and/or withdrawn Q₋ charge. To this end, preferably 0, 1, 2, 5, 10, 20, 25, 30, 35, 40, 45, 50 Ah (Q₊/Q₋) or more is exchanged with the electrochemical energy storage device during one charging cycle or a plurality of successive charge cycles respectively. It is particularly preferred for at least 0, 5, 10, 20, 25, 50, 100, 200, 500, 1000 kAh or more to be exchanged over a plurality of charge cycles.

According to a further preferential development of the method, the acquiring of measured values in accordance with S5 occurs during the charging or discharging of the electrochemical energy storage device as a function of the ratio of supplied Q₊ or withdrawn Q₋ charge to the nominal charge [Ah] or maximum charge Q_{N} of the electrochemical energy storage device respectively. It is particularly preferred for the measured values to be acquired when the Q/Q_{N} fraction more or less corresponds to integral multiples of 0.1.

According to a further preferential development of the inventive measuring method, the measured values are acquired during the charging or discharging of the electrochemical energy storage device as a function of its terminal voltage, particularly preferably at a terminal voltage of 0, 2.5; 2.7; 3.0; 3.1; 3.2; 3.3; 3.4; 3.5; 3.6; 3.7; 3.8; 3.9; 4.0; 4.1; 4.2; 4.3; 4.4; 4.5; 4.6; 4.7; 4.8; 4.9; 5.0; 5.1; 5.2 or 5.3 V.

According to a further preferential development of the inventive measuring method, the step of charging and discharging is performed multiple times successively. Thus, the electrochemical energy storage device successively assumes the first state of charge and the second state of charge multiple times. In the process, the electrochemical energy storage device runs through a predefined number of charge cycles, preferably 10, 20, 50, 100, 200, 500, 750, 1000, 1250, 1500, 1750, 2000 or more charge cycles.

An increasing number of charge cycles ages the electrochemical energy storage device. Realizing the measuring method in this way enables advantageous information to be gained on the behavior of the electrochemical energy storage device with progressive aging. Particularly preferable is thereby acquiring dimensional changes, temperatures and/or terminal voltages of the electrochemical energy storage device.

According to a further preferential development of the inventive measuring method, hereinafter referred to as M3, a temperature control of the electrochemical energy storage device occurs while same is accommodated by the receiving device, particularly at predetermined temperature gradations. Said gradations are preferably obtained from planned and/or past operation with loads. Method M3 can advantageously be combined with M1 or M2. Preferably, the electrochemical energy storage device is subjected to temperatures of −40° C., −30° C., −20° C., −10° C., 0° C., 10° C., 20° C., 30° C., 40° C., 50° C., 60° C., 70° C., 80° C. (please check). Preferably, the electrochemical energy storage device is subjected to a predetermined heat flow. Advantageously, information can be gained on the operating behavior of the electrochemical energy storage device upon cooling and/or upon the usual operating and even higher ambient temperatures. Preferably, the temperature exposure occurs at temperatures fluctuating around a target temperature, particularly by 40° C. Advantageously, the impact of a cooling device in a motor vehicle can be reconstructed.

According to a further preferential development of the inventive measuring method, the charging of a first electrochemical energy storage device as well as the discharging of a second electrochemical energy storage device occurs at the same time. Preferably, electrical energy from the first electrochemical energy storage device is thereby supplied to a second electrochemical energy storage device.

It is preferential for losses from the conversion of electrical energy into chemical energy to be equalized, in particular by a charging device (see below).

Preferably, the at least one acquired measured value is stored in a data storage device, preferably together with a value which is representative of the time of the measurement.

Preferably a control device controls steps S3, S4, S5, S6 and/or S7, particularly preferentially on the basis of predefined measuring programs and/or measuring regulations.

Preferably, acquired measured values are displayed by means of a display device and/or transmitted to an output device.

Preferably, the M1, M2 and M3 methods are applied to electrochemical energy storage devices comprising lithium.

Preferably, the inventive M1, M2 and M3 methods are applied to electrochemical energy storage devices comprising a separator which does not or only poorly conducts electrons and which consists of a substrate at least partially permeable to material. The substrate is preferably coated on at least one side with an inorganic material. An organic material which is preferably configured as a non-woven fabric is preferably used as the at least partially material-permeable substrate. The organic material, which preferably comprises a polymer and particularly preferentially a polyethylene terephthalate (PET), is coated with an inorganic, preferably ion-conducting material which further preferably conducts ions within a temperature range of −40° C. to 200° C. The inorganic material preferably comprises at least one compound from the group of oxides, phosphates, sulfates, titanates, silicates, aluminosilicates of at least one of the elements Zr, Al, Li, particularly preferentially zirconium oxide. Preferentially, the inorganic, ion-conducting material comprises particles no larger than 100 nm in diameter. Such a separator is sold for example in Germany by Evonik A G under the trade name of “Separion.”

Preferably, the inventive M1, M2 and M3 methods are applied to electrochemical energy storage devices comprising an electrode, particularly preferably a cathode, which exhibits a compound of the LiMPO₄ formula, wherein M is at least one transition metal cation from the first row of the periodic table of the elements. The transition metal cation is preferably selected from among the group consisting of Mn, Fe, Ni and Ti or a combination of these elements. The compound preferably exhibits an olivine structure, preferably primary olivine.

Preferably, the inventive M1, M2 and M3 methods are applied to electrochemical energy storage devices comprising an electrode, particularly preferably a cathode, which exhibits a compound of the LiMPO₄ formula, wherein M is at least one transition metal cation from the first row of the periodic table of the elements. The transition metal cation is preferably selected from among the group consisting of Mn, Fe, Ni and Ti or a combination of these elements. The compound preferably exhibits an olivine structure, preferably primary olivine, wherein Fe is particularly preferential. In a further embodiment, preferably at least one electrode of the electrochemical energy store, particularly preferably at least one cathode, comprises a lithium manganate, preferably LiMn₂O₄ of spinel type, a lithium cobaltate, preferably LiCoO₂, or a lithium nickelate, preferably LiNiO₂, or a mixture of two or three of these oxides, or a lithium compound oxide containing manganese, cobalt and nickel.

Preferably, the inventive M1, M2 and M3 methods are applied to electrochemical energy storage devices comprising a cathodic electrode which in one preferential embodiment at least comprises one active material, wherein the active material comprises a mixture of a lithium-nickel-manganese-cobalt mixed oxide (NMC) not of spinel structure with a lithium-manganese oxide (LMO) which is of spinel structure. Preferentially, the active material comprises at least 30 mol %, preferably at least 50 mol % NMC as well as concurrently at least 10 mol %, preferably at least 30 mol % LMO, in each case relative to the total molar number for the active material of the cathodic electrode (i.e. not relative the cathodic electrode as a whole which, additionally to the active material, can also include conductivity additives, binders, stabilizers, etc.). Preferentially, the NMC and LMO together constitute at least 60 mol % of the active material, further preferred at least 70 mol %, further preferred at least 80 mol %, further preferred at least 90 mol %, in each case relative to the total molar number for the active material of the cathodic electrode (i.e. not relative the cathodic electrode as a whole which can also include conductivity additives, binders, stabilizers, etc. additionally to the active material). Further preferentially, the active material consists substantially of NMC and LMO; i.e. no other active materials amounting to more than 2 mol %. It is thereby further preferential for the material applied to the substrate to be substantially active material; i.e. 80-95% by weight of the material applied to the cathodic electrode substrate is said active material, further preferentially 86-93% by weight, in each case relative to the total weight of the material (i.e. relative the cathodic electrode as a whole without substrate, which can also include conductivity additives, binders, stabilizers, etc. additionally to the active material). As regards the percentage by weight ratio of NMC as active material to LMO as active material, it is preferential for the ratio to range from 9(NMC):1(LMO) to 3(NMC):7(LMO), whereby 7(NMC):3(LMO) to 3(NMC):7(LMO) is preferred and whereby 6(NMC):4(LMO) to 4(NMC):6(LMO) is further preferred.

The invention also relates to a measuring apparatus for an electrochemical energy storage device. The measuring apparatus comprises a receiving device which is provided to receive at least one electrochemical energy storage device. The measuring apparatus further comprises a measuring device which is provided to detect at least one physical parameter which provides information on the operating mode of the electrochemical energy storage device accommodated in the receiving device. The measuring apparatus further comprises a charging device which is provided to at least intermittently supply and tap electrical energy to/from the electrochemical energy storage device accommodated in the receiving device.

Preferably, the supplying or discharging of energy occurs at a temporally variable current. According to the invention, in the simplest case, a charge current or discharge current is temporally constant. Preferably, the charge current is temporally variable. Preferable is first charging with a constant current until a predetermined terminal voltage can be measured. Subsequently preferable is charging with a constant voltage until the charge current falls below a minimum value. Preferably, the charge current is pulsed, wherein the pulse voltage increases over time and assumes a target voltage near the end of the charging process. It is preferable for the discharge current to be temporally variable and particularly preferential to be adapted to discharge current profiles from the actual supply of a load. The discharge current thus exhibits intervals corresponding to a motor vehicle's intermittent accelerated motion. Preferably, the discharge current corresponds to the charge of a normal driving cycle. Preferably, the discharge current is also adapted to actual environmental conditions.

Charge currents and/or discharge currents particularly for determining the states of charge of an electrochemical energy storage device with given nominal charge Q_{N}[Ah], in practice also called nominal capacity C[Ah], are in particular selected as multiples or fractional multiples of the nominal charge Q_{N} or nominal capacity C respectively of the electrochemical energy storage device. Preferably, the charge current and the discharge current of a charging cycle or a plurality of successive charging cycles respectively are harmonized:
in particular road driving cycles from which result the amounts of charge [Ah] supplied and/or discharged to/from the electrochemical energy storage device;
in particular same charge current (first value, before the slash) and discharge current (second value, after the slash) at particularly 0, 1C/0.1C; 0.25C/0.25C; 0.5C/0.5C; 1C/1C; 2C/2C; 3C/3C; 4C/4C; 5C/5C, 6C/6C, 7C/7C, 8C/8C, 9C/9C or 10C/10C;
in particular different charge current (first value, before the slash) and discharge current (second value, after the slash) at particularly 1C/2C; 1C/3C; 1C/4C; 1C/5C; 2C/1C; 2C/3C; 2C/4C; 2C/5C; 3C/1C; 3C/2C; 3C/4C; 3C/5C; 4C/1C; 4C/2C; 4C/3C; 4C/5C; 5C/1C; 5C/2C; 5C/3C; 5C/4C or another combination.

According to one preferred development, charge/discharge currents are pulsed-defined, particularly at an amperage corresponding to:
4 times the nominal capacity C or Q_{N} over a period of in particular 2 s, 8 s, 10 s, 18 s;
5 times the nominal capacity C or Q_{N} over a period of in particular 2 s, 8 s, 10 s, 18 s;
10 times the nominal capacity C or Q_{N} over a period of in particular 2 s, 8 s, 10 s, 18 s.

The substance of the terms electrochemical energy storage device, receiving device, measuring device and physical parameter have been described above.

According to one preferred embodiment, the receiving device comprises two substantially plate-shaped abutment devices arranged substantially parallel to one another. The in particular plate-shaped abutment devices are disposed so as to move relative to each other. At least one abutment device serves in particular the contact to a boundary surface of the electrochemical energy storage device or a temperature control device. The receiving device further comprises a guidance device. The guidance device serves in guiding one of the abutment devices. Preferably, the guidance device extends substantially vertically from the first abutment device toward the second abutment device. The second abutment device is supported by the guidance device so as to be relatively movable, particularly along the guidance device. Preferably, one of the abutment devices can be connected or fixed respectively vis-à-vis the guidance device, preferably in force-locking manner, particularly by means of a clamping device. It is particularly preferable for the guidance device to comprise two, three or four guide columns which extend through openings in the second abutment device.

Advantageously, the detachable connection between one of the abutment devices and the guidance device serves in realizing two different operating modes of the measuring device, M1 and M2 (see above). In the M2 operating mode with yielding receiving device, an abutment device is formed to give way particularly in consequence of a dimensional change to the electrochemical energy storage device. The measuring device thereby comprises a distance meter, wherein the distance meter particularly detects a dimensional change to the electrochemical energy storage device accommodated in the receiving device, particularly at an increasing state of charge. In the M1 operating mode with unyielding receiving device, the abutment devices exhibit a substantially unchanged spacing after receiving an electrochemical energy storage device. The measuring device thereby comprises a dynamometer, wherein the dynamometer detects a force on the receiving device from an accommodated electrochemical energy storage device, particularly at an increasing state of charge.

In the terms of the invention, a charging device refers to a device which particularly serves in the supplying of an electrical current to the electrochemical energy storage device and the drawing of an electrical current from the electrochemical energy storage device. Preferably, the charging device receives electrical energy for charging the electrochemical energy storage device from an energy source, particularly from a power network and/or from another in particular electrochemical energy storage device. Preferably, to discharge the electrochemical energy storage device, the charging device emits electrical energy to an energy sink, particularly to a power network and/or another in particular electrochemical energy storage device. Preferably, the charging device supplies a second electrochemical energy storage device both from a first electrochemical energy storage device as well as from a power network. It is particularly preferential to utilize cell/battery test systems.

A measuring apparatus according to the invention enables charge exchanges to be conducted on accommodated electrochemical energy storage devices in the laboratory and the behavior of the accommodated electrochemical energy storage devices to be detected with sensors. With the knowledge gained from these measurements, the expert is able to limit the charge currents to a tolerable degree for the electrochemical energy storage device, both in terms of amperage as well as current duration, so as to in particular counter unwanted high temperatures. Thus, irreversible chemical reactions which accelerate the aging of the electrochemical energy storage device are advantageously countered. With knowledge of the temperatures, the expert can take appropriate temperature control measures, particularly improved cooling of the electrochemical energy storage device. The knowledge puts the expert in the position of being able to design the electrochemical energy storage device receiver such that a variable dimension at different states of charge does not lead to insufficient fixing of the electrochemical energy storage device in the receiver. Thus, damage due to in particular impacts or vibration are advantageously countered. The knowledge puts the expert in the position of being able to design the electrochemical energy storage device receiver such that a variable dimension at different states of charge does not lead to damaging forces on the electrochemical energy storage device, particularly due to the receiver being dimensioned too small and the electrochemical energy storage device being constricted. Advantageously, in designing the receiver, the expert can provide for space for temporary “growth” of the electrochemical energy storage device at higher states of charge. Damage to an electrode is thus prevented. Hence, the expert gains knowledge on the improved design of an electrochemical energy storage device, a gentler operation of the electrochemical energy storage device and its accommodation in a battery for longer-lasting operation, thus accomplishing the underlying object.

The following will describe preferential developments of the inventive measuring apparatus.

According to one preferred embodiment, the measuring apparatus comprises a force actuator. The force actuator serves in subjecting the electrochemical energy storage device accommodated in the receiving device to in particular a predefined force. The predefined force amounts to serve in particular the positioning of the movable abutment devices during the M2 operating mode. In the M1 operating mode, the force actuator serves to subject the electrochemical energy storage device accommodated in the receiving device to a force which serves only an unwanted displacing of the electrochemical energy storage device in the receiving device.

According to a further preferred embodiment, the measuring apparatus comprises at least one temperature control device. The temperature control device serves in particular in subjecting the electrochemical energy storage device accommodated in the receiving device to a predefined temperature of −40° C., −30° C., −20° C., -10° C., 0° C., 10° C., 20° C., 30° C., 40° C., 50° C., 60° C., 70° C., 80° C. and/or a predetermined heat flow. Advantageously, operating conditions can be reconstructed in the laboratory. Preferably, the temperature control device contacts the electrochemical energy storage device accommodated in the receiving device in thermally conductive manner. Preferably, a temperature control medium flows through, electrically heats and/or controls the temperature control device. In one preferential development, a temperature sensor is provided and disposed to detect the temperature of a pole contact of the electrochemical energy storage device accommodated in the receiving device. Advantageously, the temperature of a pole contact serves in regulating the heat output of the temperature control device.

According to a further preferred embodiment, the measuring apparatus is designed to receive two, three, four or more electrochemical energy storage devices at the same time, advantageously saving on the time spent measuring.

Preferably, the measuring apparatus comprises a contact device which in particular serves the contacting of the accommodated electrochemical energy storage device. Particularly preferentially, the contact device is configured as an in particular spring-loaded bushing, spring clip, contact shoe, in particular spring-loaded contact bar. The contacting of the accommodated electrochemical energy storage device advantageously occurs in time-saving manner. Particularly preferentially, the contact device is equipped to contact a plurality of electrochemical energy storage devices.

Preferably, the measuring apparatus comprises an in particular disconnectable data storage device, wherein the data storage device is provided to store at least one physical parameter, preferably together with a value which is representative of the time of the measurement. Preferably, the data storage device is designed as non-volatile memory, particularly preferentially as an SD card or a USB stick.

Preferably, the measuring apparatus comprises a display device, wherein the display device is provided to display at least one acquired measured value. Preferably, the display device concurrently displays different acquired measured values which have in particular been essentially acquired at the same time. Particularly preferentially, the display device is configured as a monitor.

Preferably, the measuring apparatus comprises a control device, wherein the control device is provided to control in particular the charging device and/or the measuring device. In particular, the control device is designed particularly as a portable computer.

Further advantages, features and possible applications of the present invention will ensue from the following description in conjunction with the figures. Shown are:

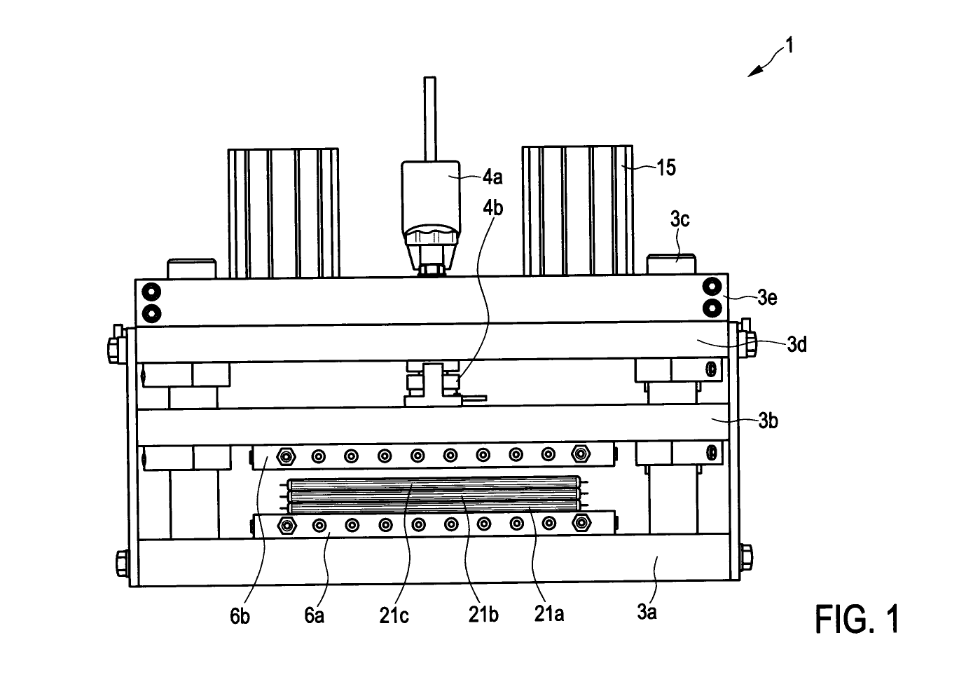

FIG. 1 a measuring apparatus according to the invention.

FIG. 1 shows an inventive measuring apparatus 1. The measuring apparatus 1 comprises a receiving device 3, shown here in the opened state. Three electrochemical energy storage devices 21a, 21b, 21c are accommodated in the receiving device 3. The electrochemical energy storage devices 21a, 21b, 21c are stacked on top of each other. Two temperature control devices 6a, 6b are likewise accommodated in the receiving device 3. A temperature control medium flows through the temperature control devices 6a, 6b and enables both cooling as well as a heating of the electrochemical energy storage devices 21a, 21b, 21c.

Not shown are the hoses for supplying temperature control devices 6a, 6b. The temperature control device 6a contacts the lower electrochemical energy storage device 21a. Not until the receiving device 3 is closed does the temperature control device 6b also come into contact with the upper electrochemical energy storage device 21c. The middle electrochemical energy storage device 21c is in thermally conductive contact with its neighboring electrochemical energy storage devices 21a, 21c.

The measuring apparatus 1 further comprises two sensors 4a, 4b which are realized as a distance meter 4a and a load cell 4b. The measuring apparatus 1 also comprises two force actuators 15, wherein the force actuators 15 are configured as pneumatic cylinders. The function of the force actuators 15 is to apply a predefined force to the electrochemical energy storage devices 21a, 21b, 21c.

Not shown are a charging device, contact device, controller, data storage and display device.

Also not depicted is that the measuring apparatus 1 comprises three temperature sensors, each connected to a respective pole contact of an accommodated electrochemical energy storage device 21a, 21b, 21c in thermally conductive manner. Advantageously, the three temperature sensors detect the temperatures of the pole contacts of the accommodated electrochemical energy storage devices 21a, 21b, 21c, particularly to support the control of the heat output of the temperature control devices 6a, 6b.

The receiving device 3 comprises a first abutment device 3a and a second abutment device 3b, configured as plates. The configuration of the abutment devices 3a, 3b is due in the present case to the prismatic form of the electrochemical energy storage devices 21a, 21b, 21c. A guidance device 3c having four cylindrical columns is connected to one of the abutment devices 3a, in the present case by means of press fitting. The second abutment device 3b, supported by ball bushings, extends along the columns of the guidance device 3c in movable fashion relative the first abutment device 3a.

The upper force actuator support plate 3e is likewise connected to the columns of the guidance device 3c. The force actuator support plate 3e supports the force actuator 15 as well as the distance meter 4a. The force actuator 15 acts on the movable yoke plate 3d. The yoke plate 3d is supported by means of ball bushings on the columns of the guidance device 3c so as to be movable in relative fashion. The force actuator 15 acts on the yoke plate 3d. The yoke plate 3d transfers the force to the second abutment device 3b via the load cell 4b. The load cell 4b is connected to the yoke plate 3d and the second abutment device 3b.

The distance meter 4a measures preferably the distance between the abutment devices 3a and 3b, in particular by means of a measuring stick which extends between the force actuator support plate 3e and the second abutment device 3b. Advantageously, the distance meter 4a indirectly measures a dimensional change, here the thickness, to the electrochemical energy storage devices 21a, 21b, 21c.

In measuring, first the receiving device 3 receives, particularly in form-locking manner, at least one electrochemical energy storage device 21a, 21b, 21c. Preferably, the at least one electrochemical energy storage device 21a, 21b, 21c is held in the receiving device 3 by a minimum clamping force F, wherein F amounts at least to 0.1 N, 0.2 N, 0.5 N, 1 N, 2 N, 5N, 10N or more. The at least one electrochemical energy storage device 21a, 21b, 21c is thereafter electrically contacted. In accordance with one particular embodiment, the contacting of the at least one electrochemical energy storage device 21a, 21b, 21c takes place prior to the receiving in the receiving device 3.

Subsequently, the at least one electrochemical energy storage device 21a, 21b, 21c is converted into a predetermined first state of charge by means of a predefined charge current I_{E}(t) (S3). Preferably, the at least one electrochemical energy storage device 21a, 21b, 21c is charged to at least 66%, 75%, 80%, 85%, 90%, 95% nominal charge Q_{N}[Ah].

Thereafter, the at least one electrochemical energy storage device 21a, 21b, 21c is converted into a predetermined second state of charge by means of a predefined discharge current I_{E}(t) (S4). Preferably, the at least one electrochemical energy storage device 21a, 21b, 21c is discharged to a maximum of 66%, 60%, 55%, 50%, 45%, 40%, 35%, 30%, 25%, 20%, 25%, 20%, 15%, 10%, 5%, 2% nominal charge Q_{N}[Ah].

During steps S3 and S5, the measuring device 4, 4a, 4b measures, particularly repeatedly, a physical parameter which provides information on the operating mode of the at least one electrochemical energy storage device 21a, 21b, 21c. Preferably, the acquiring of physical parameters occurs periodically at time intervals of predefined length, particularly after at least 1, 2, 5, 10, 20, 50, 100, 200, 500, 1000, 2000, 5000, 10,000, 20,000, 50,000 or more seconds have in each case elapsed. In accordance with one preferential development, the acquiring of physical parameters occurs after predetermined states of charge have been reached, particularly after reaching 66%, 75%, 80%, 85%, 90%, 95%, 60%, 55%, 50%, 45%, 40%, 35%, 30%, 25%, 20%, 25%, 20%, 15%, 10%, 5%, 2% nominal charge.

Preferably, steps S3 and S5 are performed repeatedly in succession.

For the first M1 measuring method with unyielding receiving device 3, the force actuator 15 is controlled such that the second abutment device 3b experiences substantially no displacement during the charging and discharging processes. In addition, the not-shown control device processes the signals from the distance meter 4a and load cell 4b for the virtually unchanged position of the second abutment device 3b.

For the second M2 measuring method with yielding receiving device 3, the force actuator is controlled such that it substantially compensates the common weight of the second abutment device 3b, yoke plate 3d and load cell 4b.

1. A measuring method for an electrochemical energy storage device comprising the steps:
receiving at least one electrochemical energy storage device in a receiving device;
electrically contacting the electrochemical energy storage device;
charging the electrochemical energy storage device at a predetermined charge current I_{L}(t) to a predetermined first state of charge;
discharging the electrochemical energy storage device at a predetermined discharge current I_{E}(t) to a predetermined second state of charge;
acquiring at least one measured value on at least one physical parameter by a measuring device which enables conclusions to be drawn as to the operating mode of the electrochemical energy storage device; and
controlling a temperature of the electrochemical energy storage device by a temperature control device to a predetermined temperature profile.

2. The measuring method according to claim 1, wherein the charging and discharging steps are performed repeatedly in succession.

3. (canceled)

4. The measuring method according to claim 1, further comprising:
acquiring at least one temperature by, the temperature control device.

5. A measuring apparatus for an electrochemical energy storage device to perform the measuring method according to claim 1, comprising:
a receiving device to receive at least one electrochemical energy storage device;
a measuring device to detect at least one physical parameter which enables conclusions to be drawn as to the operating mode of the electrochemical energy storage device accommodated in the receiving device; and
a charging device to at least intermittently supply and withdraw electrical energy to/from the electrochemical energy storage device accommodated in the receiving device.

6. The measuring apparatus according to claim 1, comprising a force actuator to apply a predefined force to the electrochemical energy storage device accommodated in the receiving device.

7. The measuring apparatus according to claim 5, comprising a temperature control device to at least intermittently exchange thermal energy with the electrochemical energy storage device, wherein the measuring device includes at least one temperature sensor.

8. The measuring device according to claim 5, wherein the electrical energy is supplied and withdrawn from the energy storage device at a predetermined time-dependent current I(t).
